(19) United States
(12) Patent Application Publication
(10) Pub. No.: US 2008/0259559 A1
(43) Pub. Date: Oct. 23, 2008

(54) Apparatus and method for controlling apparatus

(75) Inventor: Masanori Kawahara, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/898,209

(22) Filed: Sep. 10, 2007

(30) Foreign Application Priority Data
Nov. 22, 2006 (JP) 2006-316335

(51) Int. Cl. H05K 7/20; G06F 1/14

(52) U.S. Cl. 361/687; 713/501

(57) ABSTRACT

An apparatus comprises a device and a processor. The device inputs information. The processor detects an input from the device and controls the operating frequency of the processor on the basis of frequency of the detected inputs. Thus, it is possible to achieve an apparatus capable of lowering the temperature of a case when the user is using the device.

### BACKGROUND OF THE INVENTION

1. Field of the Invention

The present invention relates to an information processing apparatus having a processing unit stored in a case and input device.

2. Description of the Related Art

In PCs (Personal Computers), the amount of heat generated from integrated circuit components mounted on a processing unit increases with the advancement of functions of the processing unit. When the amount of heat generated in a PC increases, the operation of the processing unit becomes unstable. Thus, it is necessary to radiate heat appropriately.

On the other hand, there have been demands for miniaturization of a notebook-sized personal computer. Thus, the volume of a main unit provided with a keyboard, etc., has been reduced. In general, in a notebook-sized personal computer, circuit elements, such as a processing unit, etc., are disposed under the keyboard together with a printed wiring board. A palm rest portion, a touch pad, etc., are disposed at the near side of the keyboard. Furthermore, a battery pack, an expansion memory, etc., can be disposed just under each of these devices. Thus, the components are mounted in the main unit at a high density, and there is not sufficient free space around the processing unit, which is the heat generation source. Accordingly, if the heat is not radiated properly, the temperature of the case goes up, and the user who is operating the keyboard with his/her hands on the palm rest portion feels uncomfortable.

The prior art technical documents include Japanese Unexamined Patent Application Publication Nos. 11-065713, 2000-250658, and 2005-135350.

### SUMMARY

One aspect is an apparatus. The apparatus comprises an input device for inputting information and a processing unit detecting an input from the input device and controlling the operating frequency of the processing unit on the basis of frequency of the detected inputs by the detecting.

### BRIEF DESCRIPTION OF THE DRAWINGS

FIG. 1 is an overview of a PC;

FIG. 2 is a diagram (one of two) illustrating the entire configuration of the PC hardware;

FIG. 3 is a functional block diagram (one of two) of temperature control processing;

FIG. 4 is a flowchart (one of two) of the temperature control processing;

FIG. 5 is a flowchart of input monitoring processing;

FIG. 6 is a diagram (two of two) illustrating the entire configuration of the PC hardware;

FIG. 7 is a functional block diagram (two of two) of the temperature control processing; and

FIG. 8 is a flowchart (two of two) of the temperature control processing.

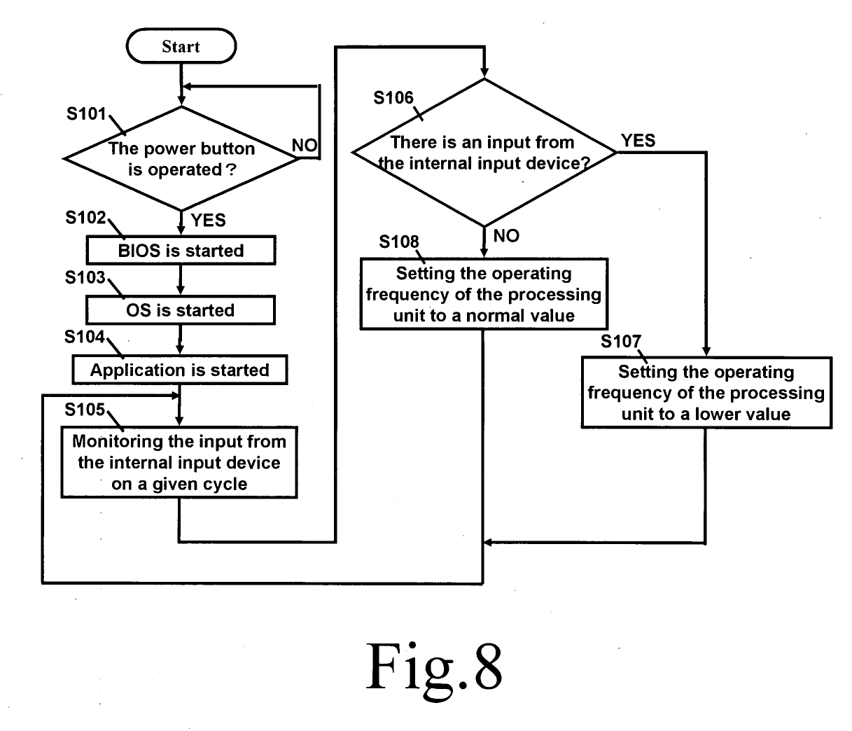

### DESCRIPTION OF THE PREFERRED EMBODIMENTS

In the following, a description will be given of an embodiment of the present invention with reference to the drawings.

### 1. First Embodiment

### Overview of PC

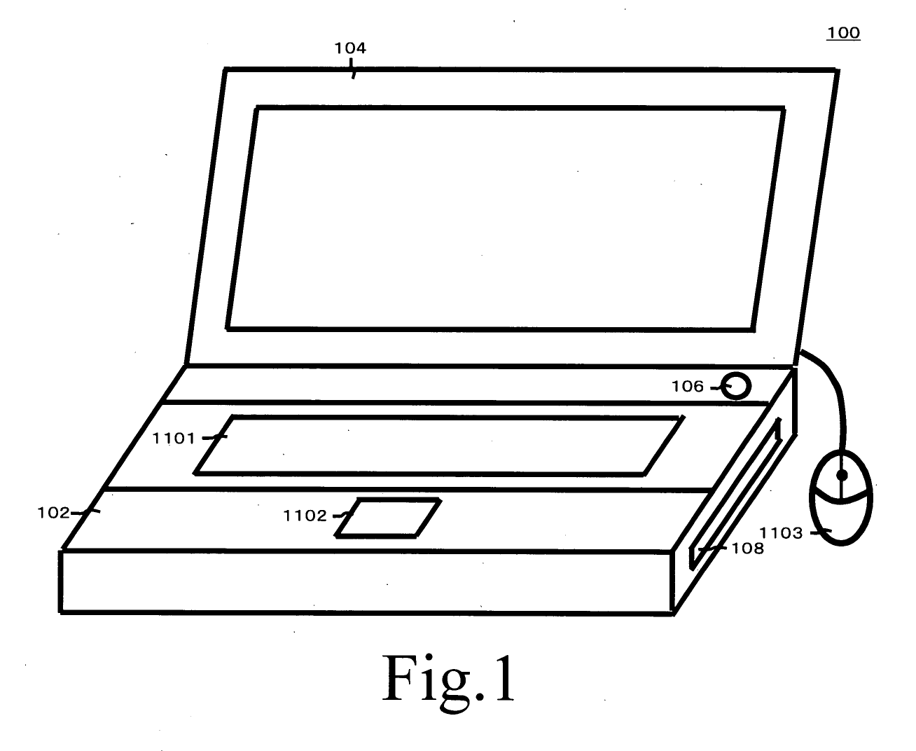

FIG. 1 is an overview of a PC, which is an example of an information processing apparatus. The PC 100 includes a case 102 including a processing unit, a memory, etc., and a display section 104 for displaying images. Furthermore, the case 102 has a keyboard 1101, which is input device for giving instructions to the PC by the user operation, a touch pad 1102 for moving a cursor on the display section 104 and giving instructions in accordance with the icon, etc., on which the cursor is placed, a power button 106 for turning on the power to the PC 100, a USB connector (not shown in the figure) conforming to the USB (Universal Serial Bus) standard, a mouse 1103 connected to the USB connector, a CD/DVD insert slot 108 to which a CD (Compact Disc) or DVD (Digital Versatile Disk) is inserted. The processing unit is disposed under the keyboard 1101, and the keyboard and the processing unit are stored in the case 102. In this regard, although not shown in the figure, an external keyboard may also be connected to the USB connector.

[Hardware Configuration Diagram of PC (1 of 2)]

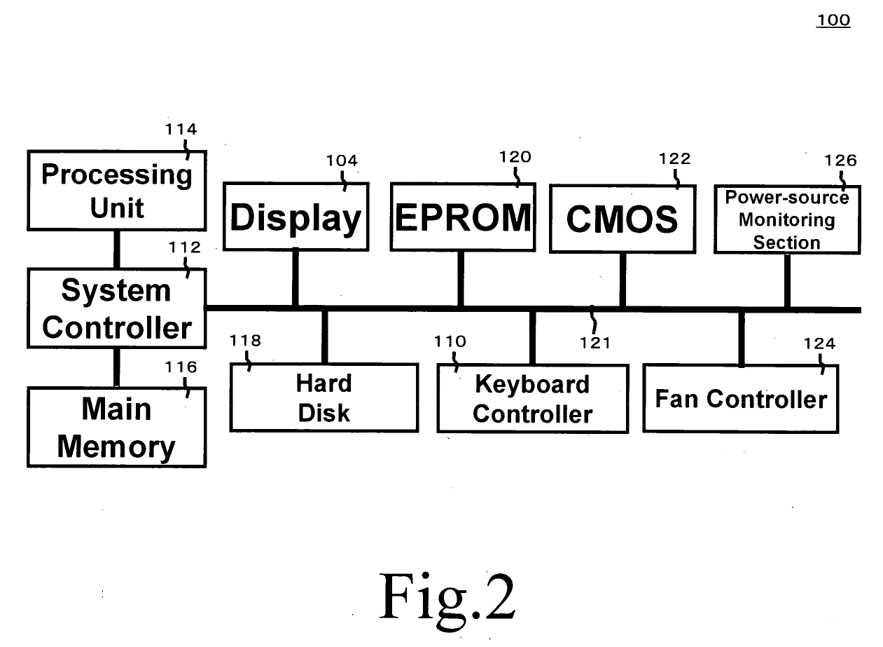

FIG. 2 is a block diagram schematically illustrating an example of the hardware configuration of the PC shown in FIG. 1. In this regard, the same reference numerals are given to the blocks as those illustrated in FIG. 1. The PC 100 has a system controller 112, a processing unit 114, a main memory 116, a display section 104, a hard disk 118, an EPROM (Erasable Programmable Read Only Memory) 120, a keyboard controller 110, a CMOS (Complementary Metal Oxide Semiconductor) 122, a fan controller 124, a power-source monitoring section 126, and a bus 121. Each block is connected to a system controller 112 through the bus 121. In the following, a description will be given of each block.

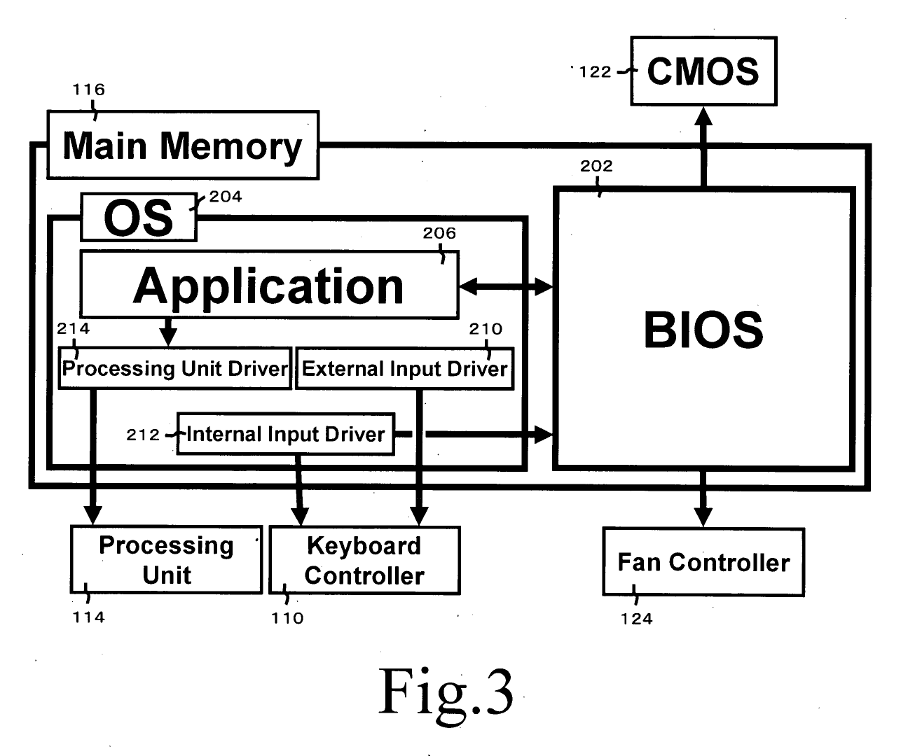

The system controller 112 controls the entire system, such as input/output control of data, etc. The processing unit 114 executes various programs, such as an OS, a BIOS, etc., which are loaded into the main memory 116. The main memory 116 is used as a work area of the programs read from the hard disk 118. In the present embodiment, the OS, the BIOS, etc., are loaded into the main memory 116. In this regard, the details will be described later using FIG. 3. The display section 104 performs image display on the basis of instructions output from the processing unit 114 through the system controller 112. The hard disk 118 stores the OS and application programs. These programs are read and loaded into the main memory 116 by the system controller 112. The EPROM 120 stores the BIOS program to be executed first after the power is turned into the PC. The keyboard controller 110 transfers the input from the keyboard 1101 and the touch pad 1102 to the system controller 112. Furthermore, the keyboard controller 110 transfers the input from the mouse 1103 and the external keyboard, which are connected to the USB connector, to the system controller 112. The CMOS 122 stores the settings of the BIOS menu. The power-source monitoring section 126 monitors whether the power button 106 has been operated. The fan controller 124 controls the number of revolutions of the fan (not shown in the figure), which is cooling unit disposed in the case 102.

[Functional Block Diagram of Temperature Control Processing]

FIG. 3 is a functional block diagram schematically illustrating an example of the temperature control processing. The temperature control function includes the main memory 116, the CMOS 122, the processing unit 114, the keyboard controller 110, and fan controller 124. A BIOS 202 and an OS 204 are loaded into the main memory 116. Furthermore, an application 206, an external input driver 210, an internal input driver 212, and a processing unit driver 214 are loaded into the OS 204. In the following, a description will be given of each block. In this regard, the same reference numerals are given to the blocks as those illustrated in FIG. 2, and the description thereof will be omitted.

[Input Driver]

The external input driver 210 and the internal input driver 212 monitor input from the keyboard controller 110. By these input drivers being loaded into the OS, the PC 100 comes to have detection means for detecting an input from the input device. The external input driver 210 monitors external input from the mouse 1103, etc., and the internal input driver 212 monitors input from the internal input device, such as the keyboard 1101, the touch pad 1102, etc. When the internal input device receives the input from the internal input device, such as the keyboard 1101, etc., the internal input driver notifies the operation key information the BIOS 202. Thus, only when input from the internal input device is received, the operation key information is notified to the BIOS 202, and thus a determination can be made on whether input is received from the internal input device or from an external input device.

[BIOS]

The BIOS 202 stores the operation key information notified from the internal input driver 212 into the CMOS 122. Also, the BIOS 202 gives an instruction the fan controller 124 by receiving an instruction from the application 206. It becomes possible for the application 206 to have versatility by giving an instruction the fan controller 124 through the BIOS 202.

[Application]

The application 206 is a control program giving instructions to the processing unit driver 214 and the BIOS 202 on the basis of the operated key information stored in the CMOS 122, and controls the processing unit 114 and a fan, which is cooling unit. The PC 100 has the processing-unit control means and the cooling control means by executing the application 206.

[Temperature Control Processing Flow]

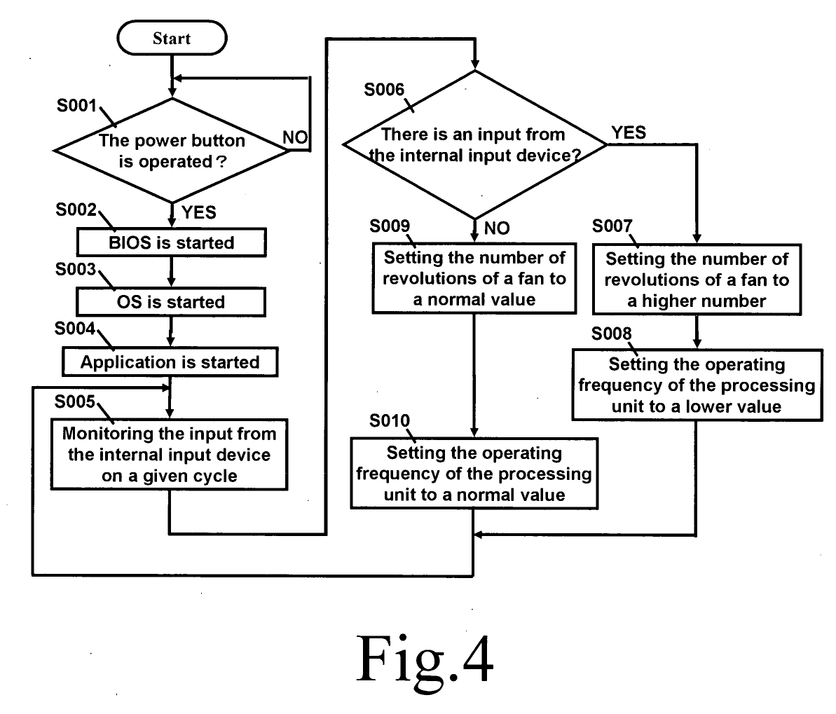

In the following, a description will be given of the temperature control processing using FIG. 4.

In step S001, the power-source monitoring section 126 determines whether the user has operated the power button 106. If the power button 106 has been operated, the processing proceeds to step S002.

In step S002, if the power button 106 has been operated, the processing unit 114 starts the BIOS stored in the EPROM 120. When the BIOS is started by the processing unit 114, the BIOS initializes the system controller 112. Then, the BIOS is loaded into the main memory 116. The processing proceeds to step S003.

In step S003, the BIOS 202 loads the OS stored in the hard disk 118 into the main memory 116, and starts the OS. The processing proceeds to step S004.

In step S004, the OS 204 loads an application stored in the hard disk 118 into the OS, and starts the application. Furthermore, the OS 204 loads an external input driver and an internal input driver stored in the hard disk 118 into the OS. The processing proceeds to step S005.

In step S005, the application 206 monitors the input from the internal input device in a predetermined period.

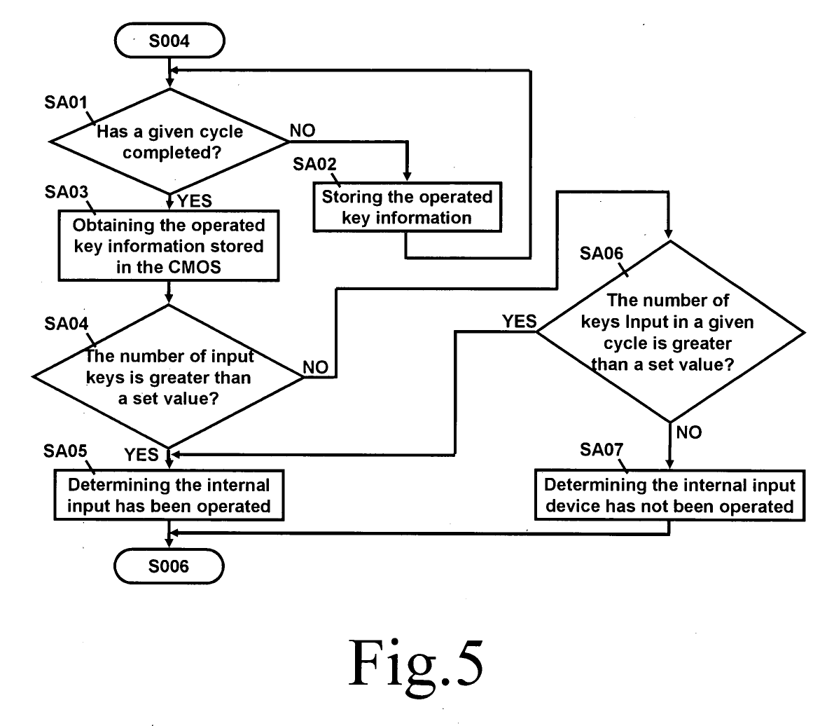

In the following, a description will be given of the input monitoring processing using FIG. 5.

[Input Monitoring Processing Flow]

In step SA01, the application 206 determines whether a predetermined period has completed on the basis of a timer in the OS. If the predetermined period has completed, the processing proceeds to step SA03. On the other hand, if the predetermined period has not completed, the processing proceeds to step SA02. In this regard, a predetermined period is set to an arbitrary value, for example “5 minutes” by the user.

In step SA02, the BIOS 202 stores the operated key information notified from the internal input driver 212 into the CMOS 122. The processing returns to step SA01, and the above-described processing is repeated.

In step SA03, the application 206 obtains the operated key information stored in the CMOS 122 in a predetermined period through the BIOS 202. The processing proceeds to step SA04.

In step SA04, the application 206 determines whether the number of input keys in a given period is greater than a predetermined value on the basis of all the operated key information obtained in step SA03. This predetermined value is arbitrarily determined by the user, and is stored in the CMOS 122. In this regard, the predetermined value is desirably determined to be a value such that the user feels uncomfortable by the heat from the case if the number of input keys in a given period is greater than the predetermined value. If the number of input keys is greater than the predetermined value, the processing proceeds to step SA05, and the application 206 determines that the internal input device has been operated. The processing proceeds to step S006. On the other hand, if the number of all input keys is not greater than the predetermined value, the processing proceeds to SA06.

In step SA06, the application 206 determines whether the number of keys input just before the end of a predetermined period is greater than the predetermined value. If the predetermined period is “five minutes” as described above, the number of keys input just before the end of a predetermined period is, for example, the number of keys input between the time “one-minute” before the end and the time when the predetermined period ends. If the number of keys input just before the end of a predetermined period is greater than a predetermined value, the processing proceeds to step SA05, and the application 206 determines that the internal input device has been operated. The processing proceeds to step S006. On the other hand, if the number of keys input just before the end of a predetermined period is not greater than a predetermined value, the processing proceeds to step SA07, and the application 206 determines that the internal input device has not been operated. The processing proceeds to step S006. Thus, even when the number of input keys in a predetermined period is not greater than a predetermined value, if the number of keys input just before the end of the predetermined period is greater than a predetermined value, it is possible to predict that the user operates the internal input device in the next predetermined period.

In step S006, the application 206 determines whether there has been an input from the internal input device. If there has been an input from the internal input device, the processing proceeds to step S007. On the other hand, if there is no input from the internal input device, the processing proceeds to step S009.

In step S007, the application 206 instructs the BIOS 202 to set the number of revolutions of a fan to a higher number than the number of revolutions of the fan when the number of inputs from the input device in a certain period of time is less than a predetermined value. When the BIOS 202 receives this instruction, the BIOS gives an instruction the fan controller 124 to set the number of revolutions to a higher number. The processing proceeds to step S008. Thus, when the user is using the internal input device for inputting, the temperature of the case can be lowered by setting the number of revolutions of the fan to a high value.

In step S008, the application 206 instructs the processing unit driver 214 to set the operating frequency of the processing unit 114 to a lower value than the operating frequency of the processing unit when the number of inputs from the input device in a given period of time is less than a predetermined value. The number of inputs from the input device is a frequency of the detected inputs. When the processing unit driver 214 receives this instruction, the processing unit driver 214 lowers the operating frequency of the processing unit 114. The processing returns to step S005. Thus, when the user is using the internal input device for inputting, the heat generation from the processing unit 114 can be restrained by lowering the operating frequency of the processing unit 114.

In step S009, the application 206 instructs the BIOS 202 to set the number of revolutions of a fan to a normal value. When the BIOS 202 receives this instruction, the BIOS 202 gives an instruction the fan controller 124 to set the number of revolutions to a normal value. The processing proceeds to step S010.

In step S010, the application 206 instructs the processing unit driver 214 to set the operating frequency of the processing unit 114 to a normal value. When the processing unit driver 214 receives this instruction, the processing unit driver 214 sets the operating frequency of the processing unit 114 to a normal value. The processing returns to step S005.

Thus, when the user inputs for a certain number of times or more, the operating frequency of the processing unit is lowered and the number of revolutions of the fan is increased. Thus, it is possible to lower the temperature of the case at the time of the user operating the keyboard.

### 2. Second Embodiment

### Hardware Configuration Diagram of PC (2 of 2)

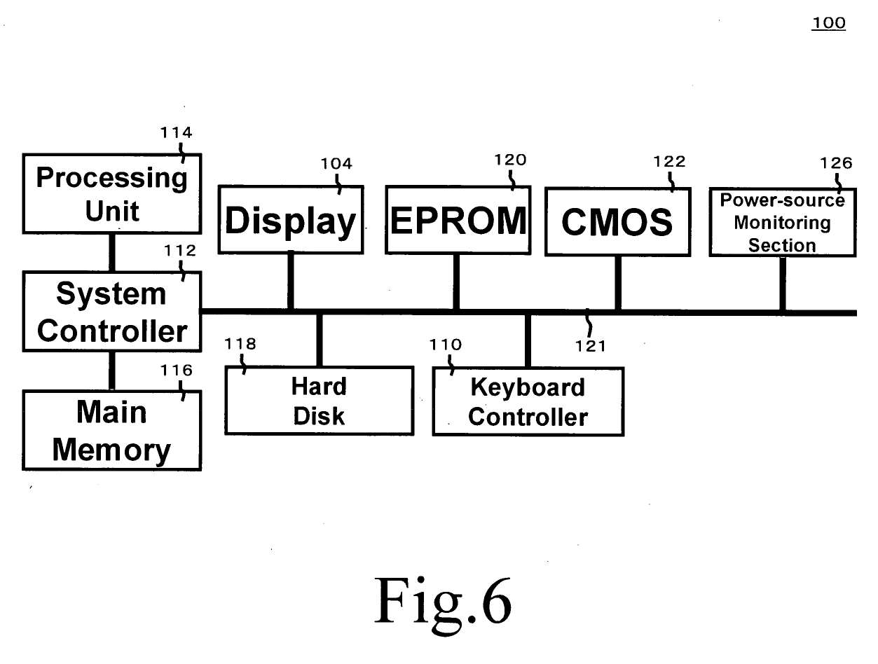

FIG. 6 is a block diagram schematically illustrating an example of the hardware configuration of a PC. In this regard, the same reference numerals are given to the blocks as those of the blocks described in FIG. 1. Compared with the first embodiment, the difference is only the point in which the fan controller 124 is not provided, and thus the description of each block is omitted.

[Functional Block Diagram of Temperature Control Processing (2)]

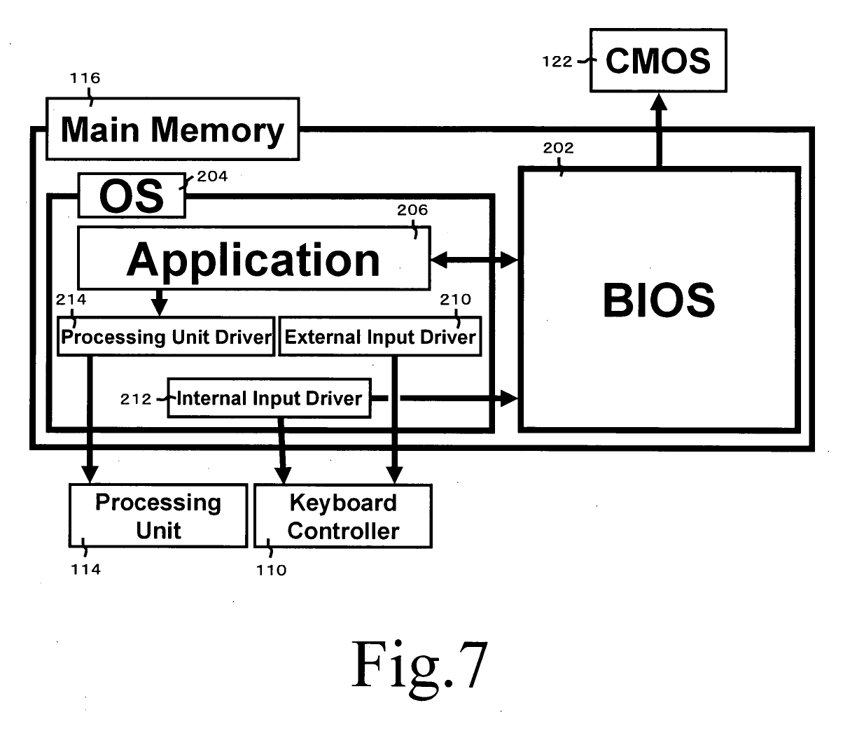

FIG. 7 is a functional block diagram schematically illustrating an example of the temperature control processing. Compared with the first embodiment, the difference is only the point in which the fan controller 124 is not provided, and thus the description of each block is omitted.

[Temperature Control Processing Flow (2)]

In step S101, the power-source monitoring section 126 determines whether the user has operated the power button 106. If the power button 106 has been operated, the processing proceeds to step S102.

In step S102, if the power button 106 has been operated, the processing unit 114 starts the BIOS stored in the EPROM 120. When the BIOS is started by the processing unit 114, the BIOS initializes the system controller 112. Then, the BIOS is loaded into the main memory 116. The processing proceeds to step S103.

In step S103, the BIOS 202 loads the OS stored in the hard disk 118 into the main memory 116, and starts the OS. The processing proceeds to step S104.

In step S104, the OS 204 loads an application stored in the hard disk 118 into the OS, and starts an application. Furthermore, the OS 204 loads various drivers stored in the hard disk 118 into the OS. The processing proceeds to step S105.

In step S105, the application 206 monitors the input from the internal input device in a predetermined period. In this regard, the input monitoring processing is the same as the processing described using FIG. 5.

In step S106, the application 206 determines whether there has been an input from the internal input device. If there has been an input from the internal input device, the processing proceeds to step S107. On the other hand, if there is no input from the internal input device, the processing proceeds to step S108.

In step S107, the application 206 instructs the processing unit driver 214 to set the operating frequency of the processing unit 114 to a value lower than the operating frequency of the processing unit when the number of inputs from the input device in a given period of time is less than a predetermined value. When the processing unit driver 214 receives this instruction, the processing unit driver 214 lowers the operating frequency of the processing unit 114. The processing returns to step S105. Thus, when the user is using the internal input device for inputting, the heat generation from the processing unit 114 can be restrained by lowering the operating frequency of the processing unit 114.

In step S108, the application 206 instructs the processing unit driver 214 to set the operating frequency of the processing unit 114 to a normal value. When the processing unit driver 214 receives this instruction, the processing unit driver 214 sets the operating frequency of the processing unit 114 to a normal value. The processing returns to step S105.

Thus, when the user inputs for a certain number of times or more, the operating frequency of the processing unit is lowered. Thus, it is possible to lower the temperature of the case at the time of the user operating the keyboard.

The above embodiments have been described specifically in order to give better understanding of the present invention, and another embodiment is not restricted. Accordingly, various changes may be made in the invention without departing from the spirit and scope thereof. For example, in the first embodiment, both the fan and the processing unit are controlled. However, the configuration in which only the fan is controlled may be allowed.

What is claimed is:

1. An apparatus comprising:
an input device for inputting information; and
a processing unit detecting an input from the input device and controlling the operating frequency of the processing unit on the basis of frequency of the detected inputs by the detecting.

2. The apparatus of claim 1, wherein the operating frequency of the processing unit is lowered when the frequency of the detected inputs from the input device becomes greater than a predetermined value.

3. The apparatus of claim 2, wherein the frequency of the detected inputs is the number of inputs from the input device in a predetermined period.

4. The apparatus of claim 1, wherein the apparatus further comprises a palm rest.

5. An apparatus comprising:
a processing unit;
an input device for inputting information to be processed by the processing unit; and
a cooling unit for cooling the processing unit, the processing unit detecting an input from the input device and controlling the cooling unit on the basis of frequency of the detected inputs by the detecting.

6. The apparatus of claim 5, wherein the processing unit controls the cooling unit by a basic input output system stored in the apparatus.

7. The apparatus of claim 5, wherein the cooling unit is a fan.

8. The apparatus of claim 7, wherein the number of revolutions of the fan is lowered when the frequency of the detected inputs from the input device becomes greater than a predetermined value.

9. The apparatus of claim 5, wherein the frequency of the detected inputs is the number of inputs from the input device in a predetermined period.

10. The apparatus of claim 5, wherein the apparatus further comprises a palm rest.

11. A method for controlling an apparatus including a processing unit and an input device for inputting information to be processed by the processing unit, the method comprising:
detecting an input from the input device; and
controlling the operating frequency of the processing unit on the basis of frequency of the detected inputs by the detecting.

12. The method of claim 11, wherein the operating frequency of the processing unit is lowered when the frequency of the detected inputs from the input device becomes greater than a predetermined value.

13. The method of claim 12, wherein the frequency of the detected inputs is the number of inputs from the input device in a predetermined period.

14. The method of claim 11, wherein the apparatus further comprises a palm rest.

15. A method for controlling an apparatus, the apparatus including a processing unit, a cooling unit for cooling the processing unit, and an input device for inputting information to be processed by the processing unit, the method comprising:
detecting an input from the input device; and
controlling the cooling unit on the basis of frequency of the detected inputs by the detecting.

16. The method of claim 15, wherein the controlling controls the cooling unit by a basic input output system stored in the apparatus.

17. The method of claim 15, wherein the cooling unit is a fan.

18. The method of claim 17, wherein the number of revolutions of the fan is lowered when the frequency of the detected inputs from the input device becomes greater than a predetermined value.

19. The method of claim 18, wherein the frequency of the detected inputs is the number of inputs from the input device in a predetermined period.

20. The method of claim 15, wherein the apparatus further comprises a palm rest.
